(19) United States
(12) Patent Application Publication
(10) Pub. No.: US 2009/0277501 A1
(43) Pub. Date: Nov. 12, 2009

(54) Solar Panel Having Improved Light-Trapping Characteristics and Method

(76) Inventor: Marvin Keshner, Hayward, CA (US)

Correspondence Address: WEISS & MOY PC, 4204 NORTH BROWN AVENUE, SCOTTSDALE, AZ, 85251, US

(21) Appl. No.: 12/117,397

(22) Filed: May 8, 2008

(51) Int. Cl. H01L 31/0232; H01L 31/0236; H01L 31/0264; H01L 31/075

(52) U.S. Cl. 136/256; 136/261; 257/E31.004; 257/E31.127; 257/E31.13

(57) ABSTRACT

A photovoltaic solar cell incorporates a light scattering material into a glass superstrate. In one embodiment, the material is in the form of a layer within the glass superstrate. In a second embodiment, the material is in the form of particles dispersed within the glass superstrate Located below the glass superstrate is a smooth conductive layer panel, which permits the smooth depositing thereon on the PIN semiconductor diode. This configuration results in fewer defects and recombination centers, and improves performance.

### FIELD OF THE INVENTION

The present invention relates to photovoltaic solar panels and, more particularly, to a photovoltaic solar panel having improved light-trapping characteristics, while reducing voids and defects in the semiconductor layer and thus improving electricity conversion.

### BACKGROUND OF THE INVENTION

Prior art thin-film solar panels are often made with thin layers of amorphous silicon or other light conversion materials. These materials are chosen for their ability to absorb light over a wide range of wavelengths and to convert the light energy into electricity. In many cases, because the layers are very thin, not all of the light may be absorbed in a single pass through the material and, instead, on a single pass of the light through the structure, only a small fraction of the light energy may be converted into electricity.

For example, in a prior-art, thin-film amorphous silicon solar panel, the silicon layer is about 0.3 um thick. Amorphous silicon absorbs strongly for short wavelengths. Therefore, the short-wavelength light (blue and green light) is absorbed in a single pass through the material. However, the longer wavelengths (orange and red light) are absorbed weakly and would require many passes through the material to be completely absorbed and converted into electricity.

It is beneficial for a solar panel to absorb and convert as much of the available light as is possible. When all of the available light is absorbed and converted into electricity, the solar cell will have a higher quantum efficiency and a lower cost per watt of electricity. Therefore, many thin-film solar cells and solar panels include some form of light trapping that bounces the longer wavelength light inside the structure so that it passes through the light converting layer or layers multiple times, to provide improved electricity conversion.

One approach is to introduce bulk or surface features that scatter the unabsorbed light. The scattered light encounters the outer surface of the panel at a higher incident angle than it would if it were not scattered. If the incident angle exceeds the critical angle at one of the interfaces between different optical materials (for example, the interface between the top of the superstrate and the outside air), the light will be totally internally reflected back toward the light-converting layer.

In the prior art, light trapping is accomplished by interposing a textured conductive layer between the glass superstrate and the semiconductor material. This is accomplished by depositing the semiconductor layer upon the textured conductive oxide layer, with the structure later being inverted for use. However, the texture of the conductive oxide creates several disadvantages for the semiconductor layer. First, the surface area of the semiconductor layer is greatly increased because it must fill in the contours of the texture. This increases dark current, lowers the open circuit voltage, and thereby lowers the power produced by the solar panel. Second, the required textures are in the range of 0.2-0.4 um. For amorphous silicon, the semiconductor layer is usually about 0.3 um thick. Because the deposited semiconductor layer is about the same thickness as the texture's contour depth, complete and uniform coverage of the texture by the semiconductor layer can be difficult to achieve consistently. Thus, while improving light trapping, the texture tends to induce voids and defects in the semiconductor layer that also reduce the power produced by the solar panel.

The present invention is directed to improving the efficiency of thin-film solar panels by depositing the semiconductor layer on a smooth rather than a textured surface and providing an optimized source of scattering elsewhere in the overall solar panel structure, such as on or in the glass superstrate.

### SUMMARY OF THE INVENTION

In accordance with an embodiment of the present invention, a photovoltaic cell is disclosed. The photovoltaic cell comprises, in combination: a glass superstrate having an upper surface and a lower surface; light scattering material disposed within the glass superstrate; wherein the light scattering material has a different index of refraction than the glass superstrate; a smooth transparent conducting layer having an upper surface and a lower surface and wherein the upper surface of the smooth transparent conducting layer contacts the lower surface of the glass superstrate; a PIN semiconductor diode below the smooth transparent conducting layer and contacting the lower surface thereof; a conducting layer positioned below the PIN semiconductor diode; and a back reflector positioned below the conducting layer.

In accordance with an embodiment of the present invention, a photovoltaic cell is disclosed. The photovoltaic cell comprises, in combination: a glass superstrate having an upper surface and a lower surface; light scattering material disposed within the glass superstrate; wherein the light scattering material has a different index of refraction than the glass superstrate; wherein the light scattering material has a melting temperature that is substantially higher than the melting temperature of the glass superstrate and an index of refraction that is substantially higher than the index of refraction of the glass superstrate; a smooth transparent conducting layer having an upper surface and a lower surface and wherein the upper surface of the smooth transparent conducting layer contacts the lower surface of the glass superstrate; a PIN semiconductor diode below the smooth transparent conducting layer and contacting the lower surface thereof; a conducting layer positioned below the PIN semiconductor diode; and a back reflector positioned below the conducting layer.

In accordance with an embodiment of the present invention, a method for converting sunlight into electricity, comprising: providing a photovoltaic cell comprising, in combination: a glass superstrate having an upper surface and a lower surface; light scattering material disposed within the glass superstrate; wherein the light scattering material has a different index of refraction than the glass superstrate; a smooth transparent conducting layer having an upper surface and a lower surface and wherein the upper surface of the smooth transparent conducting layer contacts the lower surface of the glass superstrate; a PIN semiconductor diode below the smooth transparent conducting layer and contacting the lower surface thereof; a conducting layer positioned below the PIN semiconductor diode; and a back reflector positioned below the conducting layer; positioning the photovoltaic cell so that sunlight may enter the glass superstrate and thereafter pass through the PIN semiconductor diode, where a portion of the sunlight is converted into electricity; and outputting the electricity from the photovoltaic cell.

### BRIEF DESCRIPTION OF THE DRAWINGS

FIG. 1 is a side, cross-sectional view of a prior art single-junction amorphous silicon thin-film solar panel.

FIG. 2 is a side, cross-sectional view of a prior art single-junction amorphous silicon thin-film solar panel, showing one possible path of trapped light.

FIG. 3 is a side, cross-sectional view of a single-junction amorphous silicon thin-film solar panel consistent with an embodiment of the present invention, showing one possible path of trapped light.

FIG. 4 is a side, cross-sectional view of a single-junction amorphous silicon thin-film solar panel consistent with another embodiment of the present invention, showing one possible path of trapped light.

### DETAILED DESCRIPTION OF THE PREFERRED EMBODIMENTS

As noted above, to achieve light trapping in an amorphous silicon solar panel, there must be a place in which the light is scattered so that it does not encounter the exact same angles and interfaces going out of the structure that it meets on the way into the structure. When the light exits, it has a chance to be totally internally reflected, only if at least one of the angles of the interfaces between layers is different from the angles of entry. Otherwise, any light that can enter the structure will exit the structure at the negative of the angle at which it entered.

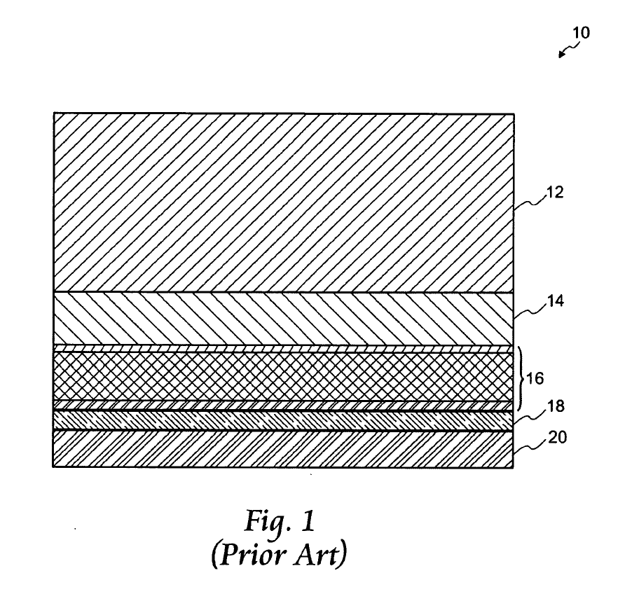

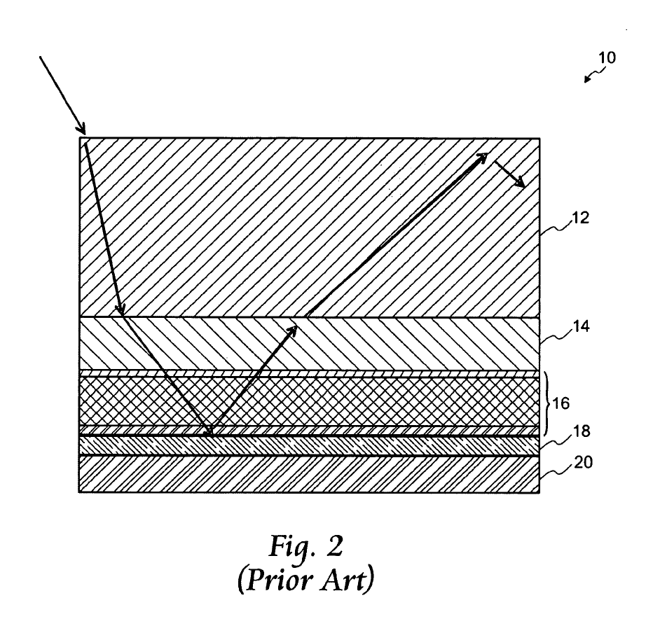

Referring to a prior-art, amorphous silicon solar panel 10 shown in FIGS. 1-2, light enters through a glass superstrate 12 and then passes through a transparent conductive oxide 14 that is textured to scatter the light. After passing through the textured conductive oxide 14, the light passes through a PIN semiconductor diode 16 of amorphous silicon that converts some of the light into electricity. The light that is not absorbed in the PIN semiconductor diode 16, then passes through ZnO layer 18 and aluminum layer 20, that together form a back conductor for the solar panel and a back reflector for the light. Most of the long wavelength light reflects and then passes back through the PIN semiconductor diode 16. Again, some of the light is absorbed. The remaining light passes again through the textured conductive oxide 14, where it is scattered again.

As shown in FIG. 2, because the light has been scattered, for most of the light, its angle at the top surface of the glass will be too shallow for the light to escape out of the glass and into the air. Thus, the light will internally reflect and make another pass through the entire set of layers on the bottom surface of the glass superstrate 12. It should be noted that FIG. 2 contains a simplified illustration of only one possible path that the light might take. Since the light is scattered randomly in the textured transparent conductor 14, many paths are possible. Also, for simplicity, the refraction of the light in the semiconductor material is not illustrated. The refraction upon entering the semiconductor layer is exactly reversed when the light is reflected and returns through the semiconductor diode. For each pass of the light, some is absorbed in the amorphous silicon layers and converted into electricity, some is absorbed by the aluminum rather than reflected, and some, in spite of the scattering in the textured conductive oxide, hits the top surface of the glass at an angle that allows it to escape rather than be totally internally reflected.

In the prior art, the number of passes through the amorphous silicon layer has been enhanced in several ways. First, the reflectivity of the back reflector can be improved by using a more reflective metal such as silver rather than aluminum. Second, assuming that the textured conductive oxide layer creates random scattering, the amount of light that will escape rather than be totally internally reflected at the glass to air interface is inversely proportional to the square of the index of refraction of the material in which the scattering takes place. Therefore, the higher the index of refraction of the scattering material, the larger the number of passes (on average) the light will take before escaping. More passes allows for more of the light to be absorbed and converted into electricity.

In prior-art, amorphous silicon solar panels, the textured, transparent conductor 14 that scatters the light is often made with SnO2, which has an index of refraction of 1.9-2.0. It can also be made with ZnO, indium tin oxide and other conductive oxides with similar indices of refraction. The size and shape of the texture can be tailored to maximize the total internal reflection, minimize the impact on the shorter wavelengths that do not need light trapping, and minimize the amount of incident light that is scattered immediately back out through the front surface rather than reaching the semiconductor layer. However, as noted above, in each case, the texture of the transparent conduct 14 tends to induce voids and defects in the PIN semiconductor diode 16, reducing efficiency.

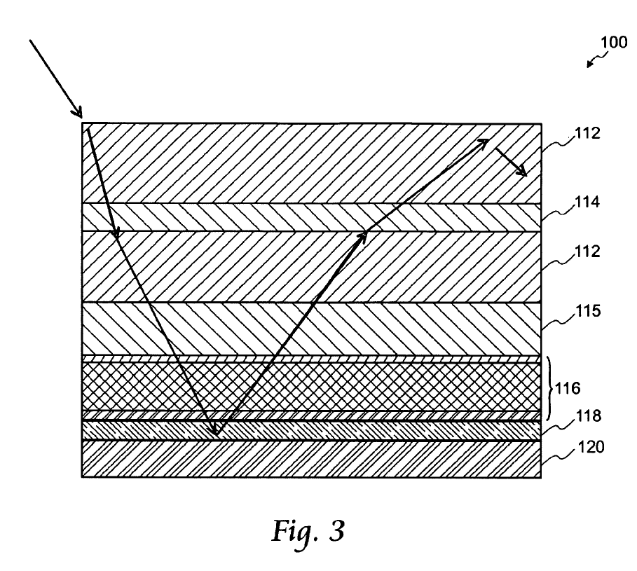

Referring first to FIG. 3, in one embodiment of the present invention, light trapping is achieved for a solar panel 100 by disposing the textured (i.e., scattering) layer 114 within the glass layer 112. A smooth (i.e., non-textured) transparent conductor 115 is positioned therebelow—i.e., interposed between the glass layer 112 and a PIN semiconductor diode 116. Positioned below the PIN semiconductor diode 116 are back conductor 118 and back reflector 120, which may be ZnO and aluminum, respectively.

The textured layer 114 should have an index of refraction that is different than the index of the glass superstrate 112. The textured material 114 should not melt and/or dissolve into the glass superstrate 112 when the glass superstrate 112 is formed around it or on top of it. In the prior art, as discussed above, the textured layer 14 is a transparent conductor that makes electrical contact to the positive terminal of the solar cell. In the embodiment shown in FIG. 3, the textured layer 114 does not have to be a conductor, and instead can be an insulator. This allows a wider choice of possible materials for the textured layer 114. Examples of suitable materials include SiC and TiO2 and others having similar properties, which include a higher index of refraction than most glasses and relatively high melting temperatures, so that they will resist melting and dissolving into molten glass.

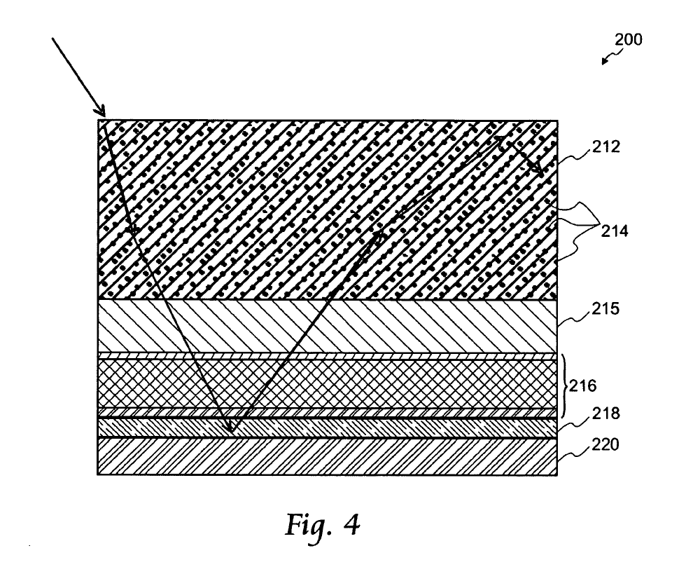

Referring now to FIG. 4, a solar panel 200 is shown, illustrating another embodiment of the present invention. In this embodiment, particles 214 of a light scattering material with a high index of refraction and a high melting temperature (as compared to glass) are mixed into molten glass before it is floated, cast or otherwise formed and cooled into a glass superstrate 212. It should be noted that adding the particles 214 just before the glass superstrate 212 is formed will assist in preventing the particles from melting or dissolving into the glass. When the glass cools, the particles 214 remain suspended in the glass superstrate 212 and will scatter light. Referring now to FIG. 4, both the top and the bottom surfaces of the glass superstrate 212 can be manufactured to be smooth.

As in the embodiment of FIG. 3, a smooth (i.e., non-textured) transparent conduct 215 is positioned therebelow—i.e., interposed between the glass layer 212 and a PIN semiconductor diode 216. Positioned below the PIN semiconductor diode 216 are back conductor 218 and back reflector 220, which may be ZnO and aluminum, respectively.

For the embodiment of FIG. 4, is should be noted that the particles must scatter the light, but not substantially absorb it. Since it is desired to have small angle scattering and to minimize the amount of light that is scattered back and out of the sun-facing surface of the glass superstrate 212, it is preferred that the particles 214 be transparent for the wavelengths that will be converted into electricity. However, it is possible to also use particles 214 that are completely reflective, such as silver. Solar panels are commonly designed to convert light into electricity over a range of wavelengths from 400-1000 nm (from near infrared light through the visible spectrum and to the edge of ultraviolet light). Therefore, the particles 214 must be transparent to all of these wavelengths of light. Second, the particles must not melt and dissolve into the glass. The particle material must retain its composition and remain distinct from the composition of the rest of the glass. Third, the scattering material must have a different index of refraction than the glass. Otherwise, it will not scatter the light, when embedded within the glass. Fourth, since the number of bounces of light within the light trapping structure is proportional to the index of refraction of the particles, the index of the scattering material should be as high as possible.

Finally, the distribution of sizes of the particles is chosen to be most effective in trapping particular wavelengths of light that are not absorbed in the first two pass through the solar panel and require multiple passes to be completely absorbed and converting into electricity. SiC and TiO2 are examples of materials that meet the criterion of being transparent from 400 nm-1000 nm, have a high index of refraction and have high melting points. For SiC, the index is very high (n=2.6), the melting temp is very high (2700 C) and the material can be made to be very transparent over the wavelengths from 400-1000 nm. For TiO2, the index is a little higher (n=2.7-2.8), but the melting temperature is lower (1800 C). The material can also be made with good transparency. In addition, there are many materials with slightly lower indices of refractions, high melting temperatures and good transparency. SiC may be particularly attractive by virtue of its very high melting temperature.

The size of the particles is chosen to best scatter light of the intended wavelength. The best scattering is usually obtained when the size of the particle is comparable to or one-half the wavelength of the light that is to be scattered, corrected for the effects of the index of refraction. For example, for a single junction amorphous silicon solar panel, it may be desired to trap the light in the range of wavelengths from 600 nm to 800 nm. Therefore, if the index of refraction (n) of the particles is one (n=1), it would be preferred to select particles with a radius in the range of 300-800 nm. With SiC, n=2.6. For this material, the radius of the particles would be roughly 100-300 nm. For a dual junction micro-crystalline silicon solar panel, the wavelengths that need to be trapped are 800-1100 nm. With particles having an index of refraction (n) of 2, the particle radii would be in the range of 400-1000 nm. For n=2.6, the range would be 300-750 nm. Thus, for the various combinations of wavelengths and materials with an even greater range for their index of refraction, the particle radii will be roughly in the range of 50-2000 nm.

There are a number of techniques to grind materials like SiC, make particles 214 therefrom, and then sort them into ranges of sizes. Particles can also be made by evaporation, chemical vapor deposition or plasma enhanced chemical vapor deposition. Any of these methods will meet the needs of this invention provided that the material remains sufficiently pure to have good transparency. Once fabricated, it may be desired to add particles of SiC to the glass just before it is formed into sheets, and to then cool the glass quickly enough so that the SiC does not melt and blend into the glass. SiC may also be incorporated into glass by precipitation.

With respect to TiO2, it can be incorporated into glass by precipitation. The particle size may be determined by the concentration of the TiO2, the rate of cooling of the interior of the glass and other parameters. The TiO2 particles can be colored by adding various transition metals, though it would be preferred to maintain the particles as clear.

In both of the embodiments of this invention described above, since the light scattering is achieved within the glass superstrate 112/212, the transparent conductor 1115/215 (e.g., SnO2), which is still required to contact the positive terminal of the solar cell or solar panel, can be smooth, rather than textured. The other layers (Silicon, ZnO and Aluminum) that are deposited on top of the transparent conductor must be deposited at low temperatures. Therefore, as discussed above, if the transparent conductor has a rough or irregular surface, then, so will the layers deposited on top of it. Depositing these layers on top of a rough surface increases their surface area and therefore, their dark current. This, in turn, reduces the open circuit voltage of the solar panel, and its efficiency in converting light into electricity. Conversely, if the transparent conductor 115/215 has a smooth surface, then each of the layers deposited on top of it will also have smooth surfaces. When the semiconductor layers of a solar panel are built on top of smooth materials, they will tend to have fewer defects and recombination centers. Defects and recombination centers also tend to lower the solar panel efficiency. Depositing the layers on a smooth surface will improve the open circuit voltage and improve the quantum efficiency or the amount of light that gets converted into electricity.

In addition, in both of embodiments of this invention described above, since the transparent conductor 115/215 that is deposited directly on the glass can be made smooth, it can also be made very thin. In the prior art, textured transparent conductors must be at least as thick as the texture that is required. Typically, this requires a thickness of 0.5-0.7 um. In this invention, the transparent conductor can be any convenient thickness, such as 10-500 nm. It could be conventional SnO2 or ZnO at conventional thicknesses, but smooth instead of textured. But, it can also be made from very thin metal layers. Metal layers of aluminum or other metals that are so thin that they become transparent to light over the range from 10-100 nm.

Although particular embodiments of the invention have been described in detail for purposes of illustration, various modifications may be made without departing from the spirit and scope of the invention. Accordingly, the invention is not to be limited, except as by the appended claims.

I claim:

1. A photovoltaic cell comprising, in combination:
a glass superstrate having an upper surface and a lower surface;
light scattering material disposed within the glass superstrate;
wherein the light scattering material has a different index of refraction than the glass superstrate;
a smooth transparent conducting layer having an upper surface and a lower surface and wherein the upper surface of the smooth transparent conducting layer contacts the lower surface of the glass superstrate;
a PIN semiconductor diode below the smooth transparent conducting layer and contacting the lower surface thereof;
a conducting layer positioned below the PIN semiconductor diode; and
a back reflector positioned below the conducting layer.

2. The photovoltaic cell of claim 1 wherein the light scattering material is disposed as a textured layer within the glass superstrate, between the upper and lower surfaces thereof.

3. The photovoltaic cell of claim 1 wherein the light scattering material is disposed as particles within the glass superstrate.

4. The photovoltaic cell of claim 3, wherein the particles are transparent.

5. The photovoltaic cell of claim 3, wherein the particles have a higher melting temperature than the glass superstrate.

6. The photovoltaic cell of claim 3, wherein the particles have a greater index of refraction than the glass superstrate.

7. The photovoltaic cell of claim 3 wherein the particles comprise one of SiC and TiO2.

8. The photovoltaic cell of claim 3, wherein the radius of the particles is in the range of about 50 to 2,000 nm.

9. The photovoltaic cell of claim 1 wherein the smooth transparent conducting layer comprises a metal.

10. The photovoltaic cell of claim 9 wherein the metal is aluminum.

11. The photovoltaic cell of claim 2 wherein the textured layer comprises one of SiC and TiO2.

12. The photovoltaic cell of claim 2, wherein the textured layer has a higher melting temperature than the glass superstrate.

13. The photovoltaic cell of claim 2, wherein the textured layer has a greater index of refraction than the glass superstrate.

14. The photovoltaic cell of claim 2, wherein the textured layer has a thickness in the range of about 50 to 2,000 nm.

15. The photovoltaic cell of claim 1, wherein the light scattering material is an insulator.

16. A photovoltaic cell comprising, in combination:
a glass superstrate having an upper surface and a lower surface;
light scattering material disposed within the glass superstrate;
wherein the light scattering material has a different index of refraction than the glass superstrate;
wherein the light scattering material has a melting temperature in excess of 1,700 C and an index of refraction in excess of 2.5;
a smooth transparent conducting layer having an upper surface and a lower surface and wherein the upper surface of the smooth transparent conducting layer contacts the lower surface of the glass superstrate;
a PIN semiconductor diode below the smooth transparent conducting layer and contacting the lower surface thereof;
a conducting layer positioned below the PIN semiconductor diode; and
a back reflector positioned below the conducting layer.

17. The photovoltaic cell of claim 16 wherein the light scattering material comprises one of SiC and TiO2.

18. The photovoltaic cell of claim 16 wherein the smooth transparent conducting layer comprises aluminum.

19. The photovoltaic cell of claim 16 wherein the light scattering material comprises an insulator.

20. A method for converting sunlight into electricity, comprising:
providing a photovoltaic cell comprising, in combination:
a glass superstrate having an upper surface and a lower surface;
light scattering material disposed within the glass superstrate;
wherein the light scattering material has a different index of refraction than the glass superstrate;
a smooth transparent conducting layer having an upper surface and a lower surface and wherein the upper surface of the smooth transparent conducting layer contacts the lower surface of the glass superstrate;
a PIN semiconductor diode below the smooth transparent conducting layer and contacting the lower surface thereof;
a conducting layer positioned below the PIN semiconductor diode; and
a back reflector positioned below the conducting layer;
positioning the photovoltaic cell so that sunlight may enter the glass superstrate and thereafter pass through the PIN semiconductor diode, where a portion of the sunlight is converted into electricity; and
outputting the electricity from the photovoltaic cell.
